(19) United States
(12) Patent Application Publication
(10) Pub. No.: US 2016/0357108 A1
(43) Pub. Date: Dec. 8, 2016

(54) PHOTOCONDUCTIVE LAYER WITH ADJUSTABLE ELECTRICAL PROPERTY

(71) Applicants: Yu-Hsiang HSU, Taipei City (TW); Green Rich Technology Co., Ltd., Chunan Miaoli (TW)

(72) Inventors: Yu-Hsiang HSU, Taipei City (TW); Jen Tau Gu, Taipei City (TW); Shih-Jue LIN, New Taipei City (TW); Hsin-Hu WANG, Taichung City (TW); Ting-Jui WU, New Taipei City (TW); I-Chun CHENG, Taipei (TW); Cheng-che HSU, Taipei (TW); Jian-Zhang CHEN, Taipei (TW); Tsun-Hsu CHEN, Taoyuan City (TW); Chih-Kung LEE, Taipei (TW)

(21) Appl. No.: 14/961,411

(22) Filed: Dec. 7, 2015

(30) Foreign Application Priority Data
Jun. 6, 2015 (TW) 104118467

(51) Int. Cl. G03F 7/20; G03G 5/06; G03G 5/047

(52) U.S. Cl. CPC G03F 7/2051; G03G 5/047; G03G 5/0696; G03G 5/0679; G03G 5/0687; G03G 5/0674; G03G 5/0664; G03G 5/06

(57) ABSTRACT

A photoconductive layer with electrical property adjustable via control of intensity or location of illumination by a light source is provided. The photoconductive layer has at least one charge generation material and at least one binder for distributing the charge generation material within the body of the layer. The localized change of electrical property in the photoconductive layer arises on and beneath the surface area of the layer illuminated by the light source via actuated bulk change in electrical charge contributed by the charge generation material in the area.

### BACKGROUND

1. Technical Field

The present invention relates in general to a photoconductive layer and, in particular, to the composite construction thereof. More particularly, the present invention relates to a photoconductive layer with varied electrical property upon excitation by light and an electrical system built using the layer.

2. Related Art

Application of photoconductive material in a conductive layer was first achieved on television and camera, for example, U.S. Pat. No. 2,730,638 discloses such use in camera tube. U.S. Pat. No. 4,265,989 discloses use as an electrode for electrophotographic application. Both describe multilayered coatings of such material for photographic image generation.

Current applications of photoconductive material are most well-established in organic photo conductor drums, such as laser printers and xerographic machines. R.O.C. Patent 1453552 discloses using a coating of photoconductive material, and surface charges can be generated on the surface. Charged areas attract fine carbon powder to transfer image onto a printing paper.

In addition to such application in organic photo conductor drums, recent developments in photoconductive material technologies emerge. For example, optoelectronic tweezer (OET) disclosed in U.S. Patent Publication No. 20090170186 uses photoconductive material and transparent electrode to form a sandwiched structure. Such is useful for controlling dielectrophoresis process in positioning suspended cells and has the advantages of simple high-precision 3-D manipulation and is, importantly, non-invasive.

Meanwhile, P.R.C. Patent Publication No. CN101709695 discloses using a UV illumination on a liquid crystal material in order to induce a mechanical bending. Such is useful in, for example, actuating a micropump.

Fundamental mechanisms of most of these applications are based on the generation of surface charges on the photoconductive material involved. Areas illuminated and unilluminated over the entire material combined determine the gross activation.

### SUMMARY OF THE INVENTION

It is an object of the present invention to provide a photoconductive layer for extending an electrical property adjustment from the surface down into the depth of the layer for creating a bulk electrical property.

It is another object of the present invention to provide a photoconductive layer with adjustable bulk electrical property for electrically matching or driving one or more secondary electrical components or smart materials.

It is still another object of the present invention to provide a photoconductive layer with adjustable bulk electrical property for secondary matching or driving via excitation by light illumination.

It is yet another object of the present invention to provide a photoconductive layer with adjustable bulk electrical property for secondary control via multiple localized light illumination with varied wavelength, luminance and shape and size of area of illumination.

In order to achieve the above and other objects a photoconductive layer with electrical property adjustable via control of intensity or location of illumination by a light source is provided. The photoconductive layer has at least one charge generation material and at least one binder for distributing the charge generation material within the body of the layer. The localized change of electrical property in the photoconductive layer arises on and beneath the surface area of the layer illuminated by the light source via actuated bulk change in electrical charge contributed by the charge generation material in the area.

In an embodiment the photoconductive layer has at least one dopant distributed within the layer.

In an embodiment of the photoconductive layer the ratio percentage of the charge generation material is above 10%.

In an embodiment of the photoconductive layer the thickness of the body of the layer is in the range of about 0.01 to 20 micrometers.

In an embodiment of the photoconductive layer the at least one charge generation material is an organic or organometallic pigments or dyes.

In an embodiment of the photoconductive layer the at least one charge generation material is one or a combination of more than one selected from organic or organometallic pigments or dyes including phthalocyanine, metal-free phthalocyanine, bisazo, triazo, squarylium, azulene system, perylene system, and naphthalene phthalocyanine.

In an embodiment of the photoconductive layer the at least one charge generation material is one or a combination of more than one hole transport material selected from (a) a compound containing at least one nitrogen atom; (b) a triphenyl amine compound; (c) a phenylenediamines compound; (d) a compound with a non-benzene ring containing a double bond; and (e) a butadiene-based compound.

In an embodiment of the photoconductive layer the dopant is one or a combination of more than one electron transport material selected from (a) organic compounds containing a carbonyl; (b) a phenanthrenequinone derivative; (c) a sulfone group-containing compound; and (d) a heterocyclic compound.

In an embodiment of the photoconductive layer the dopant is carbon nanotube.

In an embodiment of the photoconductive layer the binder is one or a combination of more than one selected from styrenic polymers, styrene-butadiene copolymer, styrene-acrylonitrile copolymer, styrene-maleic acid copolymer, acrylic polymer, styrene-acrylic copolymer, polyethylene, ethylene-vinyl acetate copolymer, chlorinated polyethylene, polyvinyl chloride, polypropylene, vinyl chloride-vinyl acetate copolymers, polyesters, alkyd resin, polyamide, polyurethane, polycarbonate, polyarylate, polysulfone, diallyl phthalate resin, ketone resin, polyvinyl butyral resin, and thermoplastic resin.

In an embodiment of the photoconductive layer the binder is one or a combination of more than one selected from silicone ketone resin, epoxy resin, phenol resin, urea resin, melamine resin and crosslinkable thermosetting resin.

In an embodiment of the photoconductive layer the binder is one or a combination of more than one selected from epoxy acrylate and urethane-acrylate light curing resin.

The present invention further provides an electrical system that has an excitation light source, a photoconductive layer and an electrical component. The photoconductive layer has an electrical property that is adjustable via control of intensity or location of illumination by the light source and the layer has at least one charge generation material distributed within the body of the layer wherein localized change of electrical property in the photoconductive layer arises on and beneath the surface area of the layer illuminated by the light source via actuated bulk change in electrical charge contributed by the charge generation material in the area. The electrical component is driven by the photoconductive layer upon actuation by the illumination of the light source.

In an embodiment of the electrical system wavelength or illuminance or both of the excitation light source are variable for controlling the electrical property of the photoconductive layer.

In an embodiment of the electrical system size or shape or both of the illumination area on the photoconductive layer are variable for controlling the electrical property of the photoconductive layer.

In an embodiment of the electrical system excitation light source further comprising a dynamic photomask for varying the size or shape or both of the illumination area on the photoconductive layer.

### BRIEF DESCRIPTION OF THE DRAWINGS

FIGS. 1A and 1B are, respectively, cross-sectional illustrations of a photoconductive layer without and with dopants according to an embodiment of the present invention.

FIGS. 2A and 2B are, respectively, cross-sectional illustrations of a photoconductive layer without and with dopants and having surface layer of conductive material according to the present invention.

FIG. 3A schematically illustrates structural layered construction of a photoconductive composite according to the present invention and FIG. 3B an optopiezoelectric micropump built using such a composite.

FIGS. 4A and 4B illustrate an optopiezoelectric dual-micropump system based on the optopiezoelectric micropump of FIG. 3B with, respectively, single and dual pumps activated.

FIGS. 5A and 5B illustrate how residual potential in the photoconductive layer can be manipulated based on adjustment to solid content of dopants according to the present invention.

FIG. 6A illustrates how charge acceptance capability of the photoconductive layer can be adjusted based on changes in the thickness thereof according to the present invention.

FIG. 6B illustrates how the layer's dependency on thickness can be reduced using a doped photoconductive layer.

FIG. 7A illustrates how charge reduce capability can be adjusted by change in solid content of the charge generation materials according to the present invention.

FIG. 7B illustrates how more dopants in photoconductive layer leads to reduced dependency of solid content of charge generation materials on charge acceptance capability according to the present invention.

FIG. 8A illustrates how resistivity of photoconductive layer can be adjusted by change in solid content of charge generation materials according to the present invention.

FIG. 8B illustrates how adding dopants into photoconductive layer leads to reduced dependency of solid content of charge generation materials on resistivity of photoconductive layer according to the present invention.

### DETAILED DESCRIPTION

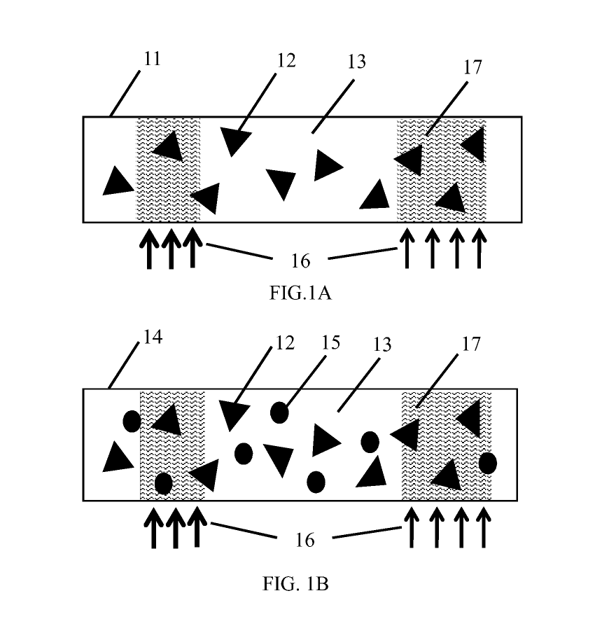

FIGS. 1A and 1B are, respectively, cross-sectional illustrations of a photoconductive layer without and with dopants according to an embodiment of the present invention. The adjustable photoconductive layer 11 of FIG. 1A includes at least one type of charge generation materials 12 and at least one type of binder 13.

Compared with FIG. 1A, the adjustable photoconductive layer 14 depicted in FIG. 1B is further doped with another type of dopant 15. Thus the layer 14 has at least one type of charge generation materials 12, at least one type of binder 13, and dopant 15 with different electrical and conductive properties (compared to layer 11).

Photoconductive layers 11 and 14 being adjustable means its electrical property can be controlled per need. Specific electrical properties adjustable include the bulk resistivity and bulk impedance, bulk dielectric constant, charge acceptance capability, charge reduce capability, light sensitivity, residual potential, and other generalized electrical properties.

Known photoconductive layer techniques implement control via control over surface charges. Adjustability of electrical properties of photoconductive layers 12 and 14 herein is based on two mechanisms. One is inherent to the composition of layer 12 and 14. Components in the composition determine the bulk electrical property under excitation by light illumination. The other is due to localized changes in electrical property both on the surface and also within the body of the photoconductive layer upon illumination. Combined, these two mechanisms allow for the adjustment of the electrical property before and after illumination. Thus charge generation in a photoconductive layer according to the present invention has two components in the working. When an area on the surface of the photoconductive layer is subject to localized light illumination, not only the surface component of the charge generation of the layer composite is excited. Light illumination penetrates down into depth of the layer also excite the body component of the charge generation. Such localized changes are bulk within their respective illumination area in the bulk in three dimension: from surface and down beneath. This local bulk property is the result of aggregated contribution by the excited charge generation material—and interaction with dopant, if present.

This bulk electrical property adjustment more than only on the layer surface but extends down into depth allows for better control of electronic devices or micro devices such as an operational amplifier or a pump.

For example, in a micropumping system such layer can provide different levels of bulk impedance via control over its excitation illumination. Driving potential is supplied through this layer and the electrical potential is divided by this layer electrically. Without illumination, this layer exhibits a high impedance and the potential on the micropump is low that there is no pumping operation. When illuminated by the light source, with the size and shape of the beam landing on the layer under control, electrical impedance of this layer can be decreased to a controlled level. Thus, electrical potential driving the micropump can be increased to a predetermined value for controlling pumping performance, either pumping slowly or quickly.

To match the need for the construction of different kinds of electronic components, electro-mechanical components, opto-electronic components, or opto-electro-mechanical components using the photoconductive layer of FIG. 1A or 1B, thickness of layers 11 and 14 as a controlling factor is in the range of between 0.01 μm and 20 μm. Further, percentage of solid content of charge generation materials 12 is, preferably, higher than 10%.

Charge generation materials 12 used in photoconductive layer 11 and 14 are, preferably but not limited to, organic, organometallic, or inorganic pigments or dyes. Here, normally, pigments are insoluble and dyes are substances with solubility. Charge generation material is blended evenly in binder 13 distributed across the entire body of layer 11 or 14.

In the case of FIG. 1B, dopant 15 with different electrical properties and blended in layer 14 can, preferably but not limited to, be a hole transport material, an electron transport material, or a carbon nanotube. Dopant 15 can also be a composition of multiple different dopants. Dopant 15 is mixed evenly with charge generation materials 12 and blended with binder 13 of the photoconductive layer 14.

Dopant 15 in photoconductive layer 14 may contain both hole and electron transport materials. Both are blended evenly with binder 13 when used. They serve as transporting materials for holes and electrons generated by charge generation material after light illumination. Solid contents of these materials can also be used as tweakable factors to adjust the bulk electrical property. Especially, ratio of solid content between hole and electron transport materials can be varied in order to adjust the electrical property of the photoconductive layer 14.

Electrical property of the photoconductive layers 11 and 14, either before or after illumination, can be adjusted by controlling density of charge generation materials 12 used for the layers.

Also, electrical property of photoconductive layer 14 before and after illumination can be adjusted by controlling the density of dopant 15.

Meanwhile, electrical property of photoconductive layer 14 before and after illumination can be adjusted by controlling its thickness.

Electrical property of photoconductive layer 14 after illumination can be adjusted by controlling wavelength of light source 16 and its illuminance. Intensity and exposure time of light source 16 can further be used to adjust electrical property of photoconductive layer after illumination.

Electrical property of photoconductive layers 11 and 14 after illumination can be adjusted by using the light source 16 to selectively illuminate designed area, such as area 17.

Electrical property of photoconductive layers 11 and 14 after illumination can be adjusted by choosing wavelength of the light source. Wavelength can, for example, be controlled using an optical filter.

Charge generation material 12 used in photoconductive layers 11 and 14 can be any type of organic, organometallic, or inorganic pigments and dyes. Preferably it includes, but is not limited to, phthalocyanine, metal free phthalocyanine, bisazo, triazo, squarylium, azulium, perylene, naphthalene phthalocyanine pigments etc. Inorganic charge generation materials can be particles or powders of selenium and its alloy, zinc oxide, amorphous silicon and amorphous silicon carbide and cadmium sulfide. Especially, these pigments and dyes can be used individually or a mixture of more than one type is also applicable.

Binder 13 of the photoconductive layers 11 and 14 can be any type of materials that is compatible with charge generation materials 12 and dopant 15. It includes preferably but is not limited to styrene polymers, styrene-butadiene copolymer, styrene—acrylonitrile copolymer, styrene—maleic acid copolymer, acrylic polymers, styrene—acrylic copolymer, polyethylene, ethylene—vinyl acetate copolymers, chlorinated polyethylene, polyvinyl chloride, polypropylene, vinyl chloride—vinyl acetate copolymer, polyester, alkyd resin, polyamide, polyurethane, polycarbonate, polyarylate, polysulfone, diallyl phthalate resin, ketone resin, polyvinyl butyral resin and polyether resin, a thermoplastic resin; silicone ketone resins, epoxy resins, phenol resins, urea resins, melamine resins, and other cross-linking thermosetting resins; epoxy acrylate and further there urethane—acrylate light curing resin. Especially, these binders can be used individually or a mixture of more than one type is also applicable.

Preferably, preparation of the coating solution of photoconductive layers 11 and 14 calls for the use of a solvent, which can be any materials that is compatible with charge generation materials 12 and dopant 15. Such solvent can be but not limited to (1) Alcohols, such as methanol, ethanol, (2) having at least four carbons: Alkanes, such as n-hexane, cyclohexane, (3) Aromati, such as toluene, xylene, (4) Halo hydrocarbons, such as dichloromethane, dichloroethane, chlorobenzene, (5) Ether, such as tetrahydrofuran, ethylene glycol dimethyl ether, (6) Ketones, such as acetone, methyl ethyl ketone, (7) Esters, such as ethyl acetate, butyl acetate, (8) Nitrogen atom solvent, such as dimethyl formaldehyde, dimethyl formamide, (9) a sulfur atom-solvent, such as dimethyl sulfoxide, and (10) water and the like, etc. Especially, these solvents can be used individually or a mixture of more than one type is applicable.

For the preparation of the coating solution for photoconductive layers 11 and 14, all components are dissolved or dispersed by the solvent. Solid content of charge generation materials 12 as a percentage to the total solid content is controlled to be 10:100 to 50:100. Further, thickness of photoconductive layer is controlled within the range between 0.01 and 20 micrometer.

In an embodiment, preparation procedure of the photoconductive layer is as follows:

(1) Preparation of the coating solution: First, a variety of coating solutions with different densities of constituents is prepared. They contain different types of charge generation materials, binders, solvents, and dopants. Each of the coating solutions contains at least one type of charge generation material, at least one type of binder, and the binder can be dissolved and dispersed in one type of solvent or a mixture of solvent and water. These coating materials can be vacuum dried, naturally dried, heat dried, light cured, or solidified by adding a curing agent.

(2) Coating and drying step: Coating solutions are applied onto a metal tube and a transparent conductor and allowed to dry. A photoconductive layer per the invention is created on the coated surfaces.

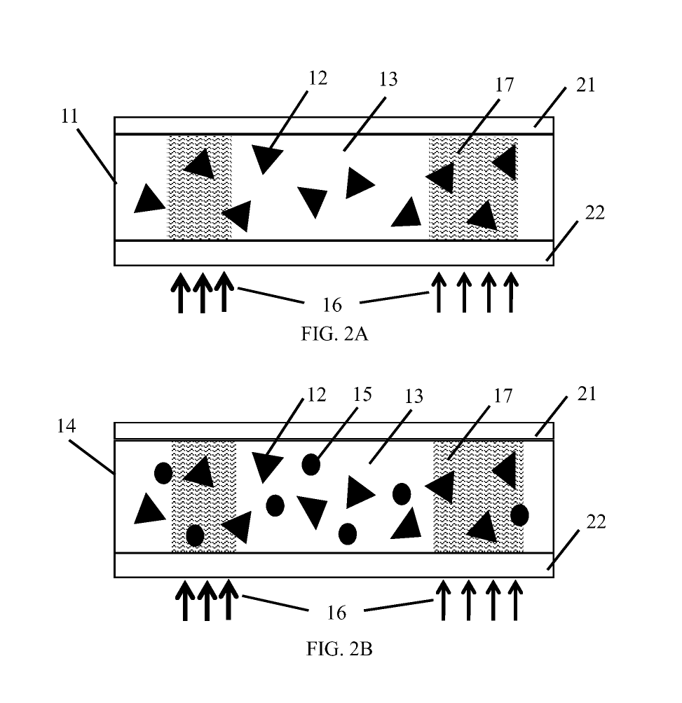

Coating solution prepared according to the above procedure can be applied to surfaces, pins, or leads of any type of circuit component for an electronic circuitry. Or, surface of the photoconductive layer can be coated with a non-transparent 21 or a transparent 22 conductive material as illustrated in FIGS. 2A and 2B respectively.

These components includes but are not limited to electronic components, electro-mechanical components, opto-electronic components, or opto-electro-mechanical components.

Photoconductive layer according to the present invention such as layers 21 and 22 depicted in FIGS. 2A and 2B can be combined with any applicable type of material to serve as structure layer and form a photoconductive composite. This photoconductive composite can respond to a light source with specific wavelength and illuminance. Especially, this structural layer can be a combination of different materials.

Structural layer of this photoconductive composite can be any kind of smart materials. This includes but is not limited to piezoelectric materials and piezoresistive materials. Further, geometry of the structural layer can be broadly varied.

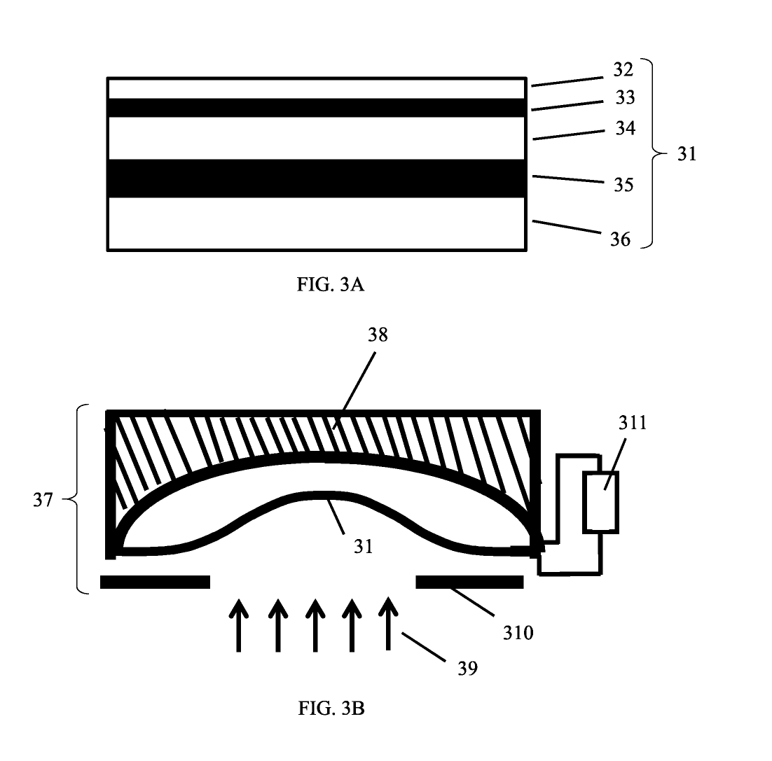

As an example, an application of a photoconductive layer on a piezoelectric thin-film for the construction of an optopiezoelectric composite 31, as is depicted in FIG. 3A. Taking advantage of the characteristic of a large electrical impedance drop across the photoconductive layer with and without light illumination, a driving voltage fed across the optopiezoelectric composite renders practical controlled actuation capability. FIG. 3A illustrates one example of optopiezoelectric composite, which includes a metallic electrode 32, a piezoelectric layer 33 (a polyvinylidene fluoride (PVDF) in this example), a photoconductive layer 34, a transparent conductive electrode 35 (indium tin oxide), and a polymer-based structural layer 36 (Parylene-C).

The above optopiezoelectric composite 31 can be useful in a microfluidic system for, for example, a Lab-on-a-Chip system. FIG. 3B exemplifies such use of the present invention in which an optopiezoelectric composite is the basis for the construction of an optopiezoelectric micropump 37. This optopiezoelectric micropump includes an optopiezoelectric composite 31, a hemisphere microchamber 38, an excitation light source 39, a photomask 310, and a driving AC voltage source 311. The driving AC voltage is fed across the metallic electrode 32 and the transparent conductive electrode 35. With the photomask 310 masking the light source 39, optopiezoelectric composite 31 can be selectively exposed. As a result, electrical impedance of the exposed area is significantly reduced. In one example embodying an application of the present inventive photoconductive layer shows that the impedance change can be as large as 2 to 3 orders of magnitude. With this mechanism, electrical potential across the piezoelectric layer 33 in the region of exposed area can be increased greatly. The piezoelectric layer is thus actuated and produces a large mechanical deformation to push fluid for pumping.

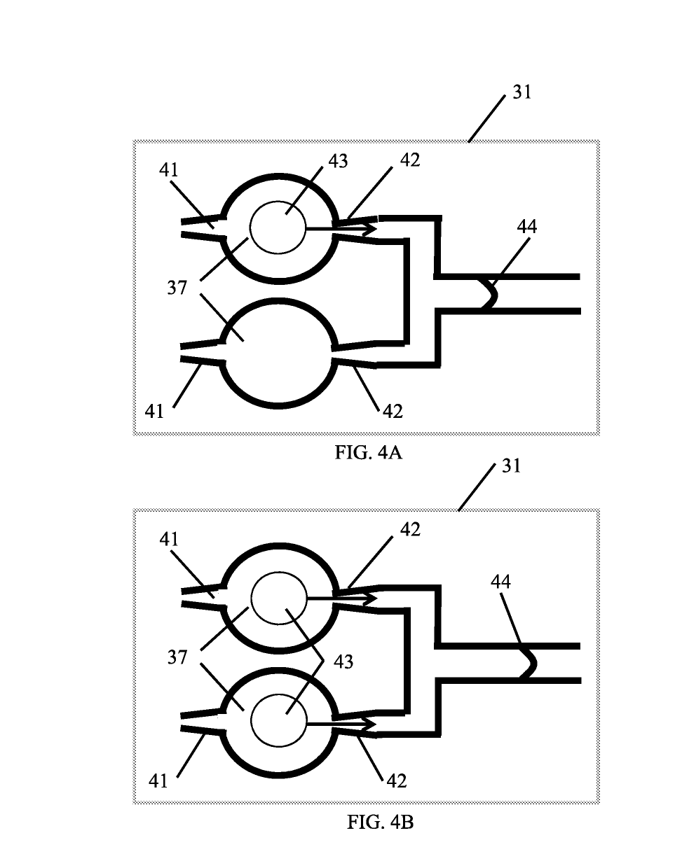

As another example, an embodiment of the present invention uses the optopiezoelectric micropump 37 in an optopiezoelectric dual micropumping system shown in FIGS. 4A and 4B. Only one optopiezoelectric composite 31 is needed for both optopiezoelectric micropumps 37. A valveless nozzle/diffuser (41 & 42) is provided to each pump for controlling the direction of fluid flow. Excitation light source is masked by photomask 310 to selectively illuminate a control area 43 on each pump. FIG. 4A illustrates a scenario in which one of the optopiezoelectric micropumps is activated by illuminating only one pump. Fluid flow 44 emerges as a result. FIG. 4B illustrates how both optopiezoelectric micropumps are activated by illuminating both pumps, and fluid flow 44 is doubled. In one example of such an optopiezoelectric dual micropumping system, volumetric flow rate of when a single pump is activated is 0.652 microliter/min. The volumetric flow rate reaches 1.178 microliter/min when both pumps are activated. This is 1.806 times faster than single pump. It also demonstrates that with just one optopiezoelectric composite the number of activated micropumps can be selectively controlled by the use of a masked light source.

Electrical property of photoconductive layer of the optopiezoelectric composite 31 shown in FIGS. 4A and 4B can be adjusted by controlling the ratio of the solid contents between charge generation material 12 and dopant 15. Thickness of the photoconductive layer can be another control factor.

Light source 43 shown in FIGS. 4A and 4B can be a dynamically controlled light source that can be selectively to illuminate each individual pump. Alternatively, photomask 310 can be a dynamic photomask that selectively masks each pump. Using either a dynamic light source or a dynamic photomask, optopiezoelectric micropumps can be selectively activated individually. They can be controlled sequentially, spatially, or intermittently. Thus, electrical impedance can be selectively adjusted for the control of the driving potential 33 across the piezoelectric layer 33. Pumping force can thus be adjusted for control of fluid flow.

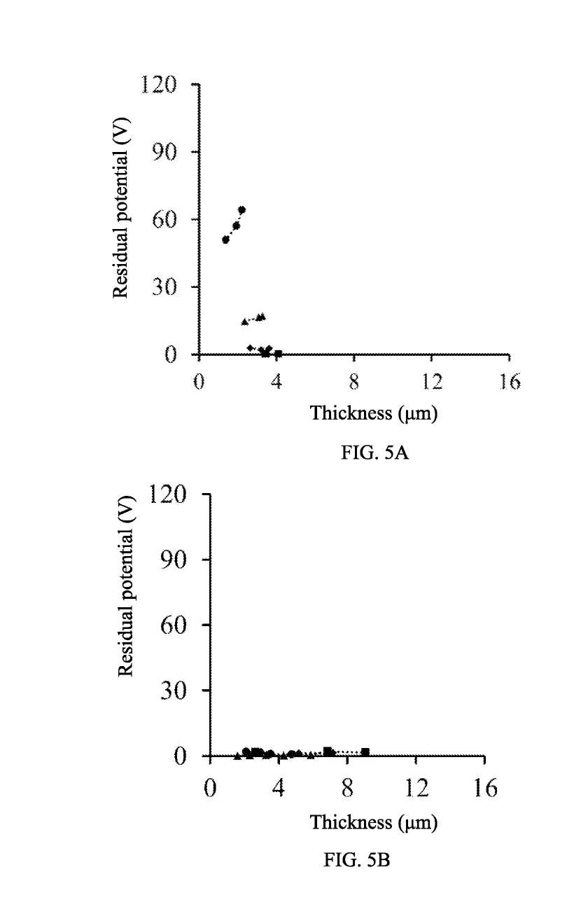

In yet another example of the present invention, dopant 15 is introduced into the system to control the residual potential. FIG. 5A shows the residual potential of the photoconductive layer under different solid contents of charge generation material 12 in the photoconductive layer 11. FIG. 5B shows the residual potential of the photoconductive layer with different solid contents between charge generation material 12, and dopants 15 used in photoconductive layer 14. Dopant used in this example may be hole transport material or electron transport material. This example demonstrates that adding dopants into the photoconductive layer, the residual potential can be significantly reduced.

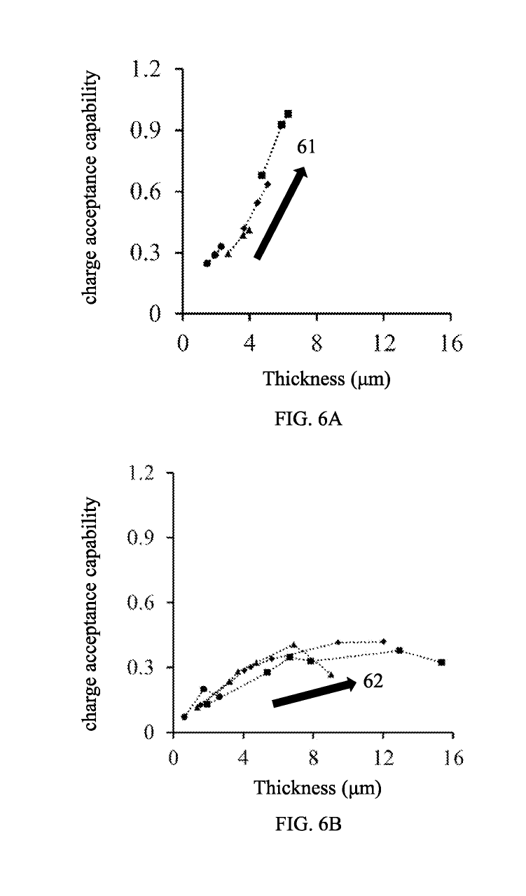

In still another example of the present invention, physical thickness of the photoconductive layer is used as a factor to control the charge acceptance capability. FIG. 6A shows thickness dependency of the charge acceptance capability of the photoconductive layer 11 with different solid content of charge generation materials 12. Arrow 61 in FIG. 6A indicates the increase of concentration of charge generation materials from 10 to 50%.

In another example of the present invention, hole transport material and electron transport material serve as dopants 15 for reducing as well as adjustment of the thickness dependency on the charge acceptance capability. FIG. 6B shows this thickness dependency of the photoconductive layer 14 under the condition of different solid content of charge generation materials 12 and dopants 15. Arrow 62 in FIG. 6A indicates an increase of concentration of charge generation materials from 10 to 50%.

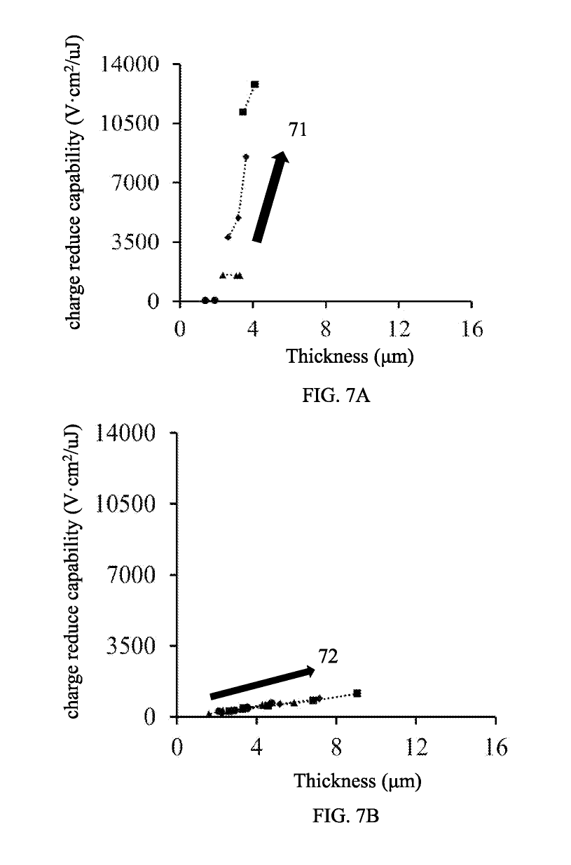

In another example of the present invention, solid content of charge generation materials 12 is a factor for adjustment in the charge reduce capability. FIG. 7A shows such dependency of solid content of charge generation materials on the charge reduce capability of the photoconductive layer 11. Arrow 71 shown in FIG. 7A indicates an increase in the concentration of charge generation materials from 10 to 50%.

In another example of the present invention, hole transport material and electron transport material serve as dopants 15 in the photoconductive layer 14 for reducing as well as adjusting the dependency of solid content of charge generation material against the charge reduce capability. FIG. 7B shows dependency of solid content of charge generation material against charge reduce capability of the photoconductive layer 14. Arrow 62 in FIG. 6A indicates an increase of the concentration of charge generation materials from 10 to 50%.

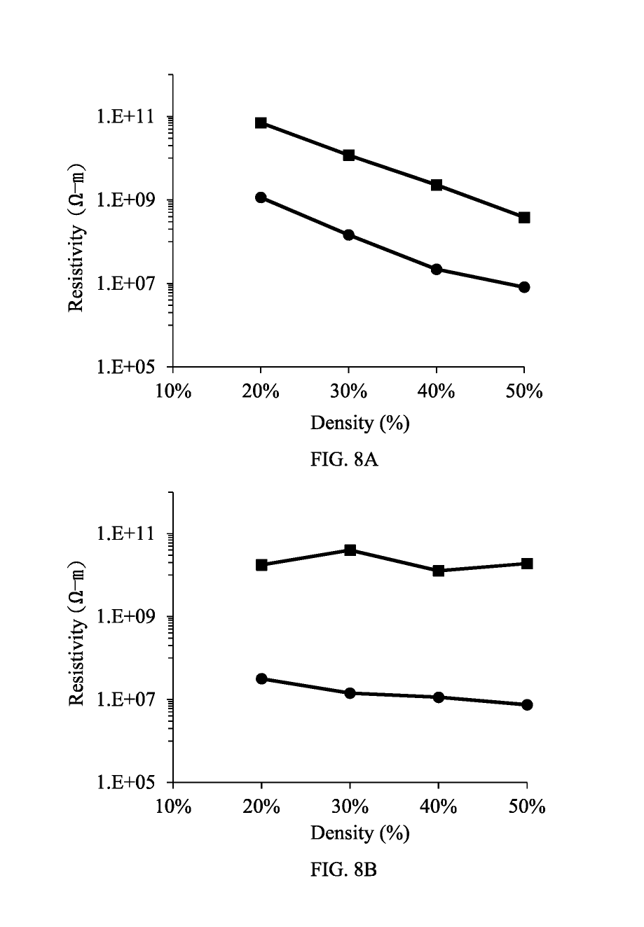

In another example of the present invention, solid content of charge generation materials 12 can be used to adjust the resistivity. FIG. 8A shows the dependency of solid content of charge generation materials on resistivity of the photoconductive layer 11.

In another example of the present invention, hole transport material and electron transport material serve as dopants 15 in photoconductive layer 14 for reducing the dependency of the solid content of solid content of charge generation material on the resistivity. FIG. 8B shows the dependency of solid content of charge generation material on resistivity of photoconductive layer 14 with added dopants 15.

While the above is a full description of specific embodiments of the present invention, various modifications, alternative constructions and equivalents may be used. For example, photoconductive layer of the present invention is equally suitable for application to components used in compact disc players, precision instruments of all kinds, and robotic devices. Therefore, the above description and illustrations should not be taken as limiting the scope of the present invention which is defined by the appended claims.

What is claimed is:

1. An electrical system comprising:
an excitation light source;
a photoconductive layer with electrical property adjustable via control of intensity, location, size, or shape of illumination by the light source, the layer comprising:
at least one charge generation material distributed within the body of the layer wherein localized change of electrical property in the photoconductive layer arises on and beneath the surface area of the layer illuminated by the light source via actuated bulk change in electrical charge contributed by the charge generation material in the area; and
at least one binder for distributing the charge generation material within the body of the layer; and
at least one electrical component driven by the photoconductive layer upon actuation by the illumination of the light source.

2. The electrical system of claim 1 wherein wavelength or illuminance or both of the excitation light source are variable for controlling the electrical property of the photoconductive layer.

3. The electrical system of claim 1 wherein size or shape or both of the illumination area on the photoconductive layer are variable for controlling the electrical property of the photoconductive layer.

4. The electrical system of claim 1 wherein the excitation light source further comprising a dynamic photomask for varying the size or shape or both of the illumination area on the photoconductive layer.

5. The electrical system of claim 1 wherein the photoconductive layer further comprising at least one dopant distributed within the layer.

6. The electrical system of claim 1 wherein the percentage of the charge generation material in the photoconductive layer is above 10%.

7. The electrical system of claim 1 wherein the thickness of the body of the photoconductive layer is in the range of about 0.01 to 20 micrometers.

8. The electrical system of claim 1 wherein the at least one charge generation material is an organic or organometallic pigments or dyes.

9. The electrical system of claim 1 wherein the at least one charge generation material is one or a combination of more than one selected from the group consisting of organic or organometallic pigments or dyes including phthalocyanine, metal-free phthalocyanine, bisazo, triazo, squarylium, azulene system, perylene system, and naphthalene phthalocyanine.

10. The electrical system of claim 5 wherein the dopant in the photoconductive layer is one or a combination of more than one hole transport material selected from the group consisting of
(a) a compound containing at least one nitrogen atom;
(b) a triphenyl amine compound;
(c) a phenylenediamines compound;
(d) a compound with a non-benzene ring containing a double bond; and
(e) a butadiene-based compound.

11. The electrical system of claim 10 wherein the compound of (a) containing at least one nitrogen atom is hydrazone.

12. The electrical system of claim 10 wherein the compound of (d) with a non-benzene ring containing a double bond is stilbene.

13. The electrical system of claim 5 wherein the dopant is one or a combination of more than one electron transport material selected from the group consisting of
(a) organic compounds containing a carbonyl;
(b) a phenanthrenequinone derivative;
(c) a sulfone group-containing compound; and
(d) a heterocyclic compound.

14. The electrical system of claim 13 wherein the compound of (a) containing a carbonyl is bis carbonyl compound selected from the group containing diphenolquinone series and naphthalenone series.

15. The electrical system of claim 13 wherein the phenanthrenequinone derivative of (b) is phenanthrenequinone.

16. The electrical system of claim 13 wherein the heterocyclic compound of (d) is selected from the group containing pyrazolidine and thiophene compounds.

17. The electrical system of claim 5 wherein the dopant is carbon nanotube.

18. The electrical system of claim 1 wherein the binder is one or a combination of more than one selected from the group consisting of styrenic polymers, styrene-butadiene copolymer, styrene-acrylonitrile copolymer, styrene-maleic acid copolymer, acrylic polymer, styrene-acrylic copolymer, polyethylene, ethylene-vinyl acetate copolymer, chlorinated polyethylene, polyvinyl chloride, polypropylene, vinyl chloride-vinyl acetate copolymers, polyesters, alkyd resin, polyamide, polyurethane, polycarbonate, polyarylate, polysulfone, diallyl phthalate resin, ketone resin, polyvinyl butyral resin, and thermoplastic resin.

19. The electrical system of claim 1 wherein the binder is one or a combination of more than one selected from the group consisting of silicone ketone resin, epoxy resin, phenol resin, urea resin, melamine resin and crosslinkable thermosetting resin.

20. The electrical system of claim 1 wherein the binder is one or a combination of more than one selected from the group consisting of epoxy acrylate and urethane-acrylate light curing resin.

21. The electrical system of claim 1 wherein the electrical system is a piezoelectric micropumping system compromising at least one micropump.
